(19) United States
(12) Patent Application Publication
(10) Pub. No.: US 2012/0152317 A1
(43) Pub. Date: Jun. 21, 2012

(54) HIGH CONCENTRATION PHOTOVOLTAIC MODULE

(75) Inventors: Fernando Celaya Prieto, Sevilla (ES); Antonio De Dios Pardo, Sevilla (ES); Carlos Martin Maroto, Sevilla (ES)

(73) Assignee: ABENGOA SOLAR NEW TECHNOLOGIES S.A., Sevilla (ES)

(21) Appl. No.: 13/379,804

(22) PCT Filed: Jun. 22, 2010
(86) PCT No.: PCT/ES2010/070415

§ 371 Date: Jan. 13, 2012

(30) Foreign Application Priority Data
Jun. 22, 2009 (ES) P200930336

(51) Int. Cl. H01L 31/052

(52) U.S. Cl. 136/246

(57) ABSTRACT

A high concentration photovoltaic module, including a plurality of Fresnel concentrating lenses, serving as lenses for solar radiation concentration, which form a group or array arranged on a “V” shaped structure, which reduces the amount of air contained therein, thus minimizing effects of moisture on active elements of the system, attached by a sealed attachment mechanism, and wherein, at the base, there are a plurality of predetermined cavities each of which house a photovoltaic receiver including at least one photovoltaic cell on which a secondary optical element is placed, improving acceptance angle, thus multiplying electric energy generation capacity of the photovoltaic cells and durability thereof, and includes side parts screwed to the structure which minimize torsion stress caused by attachment to the tracker.

### FIELD OF THE INVENTION

The present invention refers to a high concentration photovoltaic module (“HCPV”) making use of an array of Fresnel lenses, a secondary optical system and high efficiency photovoltaic cells for producing electric energy. Furthermore, the present invention refers to a manufacturing and assembly process of said high concentration photovoltaic module.

### BACKGROUND ART

Solar energy is frequently considered to be a renewable alternative to energy generated from fossil fuel, which is currently the predominantly used source. Naturally, cost is a main factor for determining the type of energy source to be used, and it can be reasonably expected that when the cost of energy created from the conversion of solar power becomes competitive to that generated from fossil fuels, use of solar energy will become more widespread.

Solar energy conversion modules that convert solar light into electric energy typically employ photovoltaic cells that directly convert solar energy into electric energy. Photovoltaic solar cells are devices capable of transforming solar radiation into electricity directly. The amount of energy created by the cell is directly related to the amount of solar energy that the cell absorbs; the amount of energy that the cells absorb is, in turn, a function of both the size and the surface area of the cell, the intensity of solar light and the wavelength incoming the cell.

High photovoltaic concentration is an incipient technology that is beginning to position itself as a low cost energy generation alternative.

The high manufacture cost of photovoltaic cells, mainly due to the costs of the cells, that in large part are imported from other countries, results in the sale price being excessively high.

In relative terms, the photovoltaic cell is the most expensive component of a solar energy converter. Therefore, increasing the energy produced by the converter by increasing the surface areas of the cells can be very expensive, and, thus, normally other methods are employed for increasing the light intensity incoming the cell. Such methods include concentrating lenses and/or mirrors to focus solar light on the cell.

The size of the module also affects the cost in other indirect ways. Given that the majority of solar energy converters are manufactured far from the installation site, transportation and final assembly costs can be substantial. Clearly, transportation costs can be minimized by reducing the size of the converter module, and it can be reasonably expected that simplifying the general structure would lower assembly costs, as well as the cost of the solar collector itself.

Indeed, in semiconductor material, installing a megawatt-peak of conventional photovoltaic modules requires a space equivalent to a football pitch (8,000 m²). Conversely, in the case of high photovoltaic concentration modules, the necessary semiconductor surface is reduced to eight square meters (8 m²). This shows the economic advantages of this technology, as the use of less space for installations and solar farms composed of high concentration photovoltaic modules is much lower.

With regard to the above, it is important to point out that conventional photovoltaic cells are manufactured with silicon, whereas those used in high concentration are generally made from periodic table elements from groups III-V, such as gallium, indium, phosphorus and others of the same type usually on germanium substrates, forming tandem or multijunction cells that enable a much more efficient use of the solar spectrum.

In the case of silicon cells, being of a single junction, the theoretical conversion limit, determined by its efficiency, is found at 40% (in concentration conditions). Conversely, for multijunction cells, the theoretical limit is found at eighty six point four percent (86.4%), thus there is a very high potential for improvement.

Currently, commercial silicon cells (for one sun) have a maximum efficiency of twenty one percent (21%) (monocrystalline silicon), whereas the triple junction cells have efficiencies of around thirty seven percent (37%).

Currently, the majority of conventional silicon photovoltaic installations have efficiencies of less than fifteen percent (15%). Consequently, the total area of solar photovoltaic collection can be drastically reduced by use of high photovoltaic concentration modules (almost half currently, fifty percent (50%) of the surface area required by conventional photovoltaic installations, and with, even, a potential reduction of this percentage). This reduction of the total surface area for the installed equivalent peak power, by means of high concentration photovoltaic modules, reduces the cost of important elements in the installation:
a) less land needed,
b) fewer solar trackers,
c) shorter distances for cabling and other structural elements,
d) reduced shipping costs due to lower volume and weight of necessary elements.

As a result of the above, there is a large potential for reducing the installed cost per watt.

In some countries, such as Spain, rooftop electric photovoltaic electric power generating installations are favored over land-based plants; consequently the technological advances should center on said installations.

A related object is to provide a solar energy converter of this type which uses an individual lens or optical concentrator reinforced with a secondary optical element for each cell.

The system for applying solar radiation concentration lenses on photovoltaic cells for increasing the electric energy production capacity of the cells, consists on using a concentration lens made of glass, methacrylate, polyurethane, polyethylene, polypropylene or any other similar type of material that is transparent to allow solar rays to pass. Fresnel lenses, having the properties to act as large power solar radiation concentrators and, consequently, allow to take advantage of said energy in the field of photovoltaic energy.

Circular and concentric circles are etched along the full width of the diameter of the lens, which serve as the element that allows the lens to concentrate solar radiation. In short it is a conventional type of solar radiation concentration lens of the type found in the market. Its dimensions are usually between 10/30 centimeters in diameter, said measurements varying in accordance with the requirements of the use it is to be given.

Said lens is placed on a frame or chassis having a smaller double bottom for placing the photovoltaic cell, with a separation of between 10/30 centimeters from the concentration lens. With the array oriented towards the position of the sun, the rays income the lens and pass through it until reaching the photovoltaic cell, which receives said solar radiation with increased power due to a larger radiation surface on passing through the concentration lens and the additional secondary optical element.

Units deployed in this way, namely the array of a concentration lens, superimposed on a photovoltaic cell at a distance of between 10/30 centimeters, with both elements supported by a box or chassis, can be placed in series to form photovoltaic modules, and in the necessary number needed to reach the power in watts that wants to be determined in each module, bearing in mind the energy production capacity of each cell based on the improved performance obtained by the efficiency of the concentration lens.

On the other hand, it is important to point out that as opposed to other proven technologies in installations for many years, as of yet high concentration photovoltaic technology does not have any plants in operation for an extended period of time. It is essential, therefore, to provide products that guarantee long term reliability.

The majority of high photovoltaic concentration modules known in the market are a closed type, as taught in patent ES2229950, in which an enclosing structure or carcass having lenses on its top external surface, contains many active elements (cells, protection diodes) and wiring.

The cited elements are very sensitive to moisture and contact with it results in accelerated deterioration that can limit its lifespan in acceptable operating conditions. Even if encapsulating systems are incorporated to these elements, it is extremely important for the receiver to impede the entry of moisture or other external elements so as to avoid these effects.

Existing modules in the market have not satisfactorily provided the necessary sealing, as is the case of patent ES2267382 the structure of which besides not ensuring sealing as it is formed by a central “U” shaped section and two lateral wings that are attached by attaching means such as resins, in the event of a breakdown or malfunction of any of the pieces in the interior, it is necessary to break the module in order to gain access to its interior. Moreover, a factor to be taken into account is the issue of relative humidity that is produced inside the module, that has direct effects on the active system elements.

Also, current locks require the use of adhesive materials that prevent or make difficult replacing the lenses or other elements in the module.

Furthermore, high structural rigidity is required so that the structure will behave adequately before the demands that it is going to have to endure during the lifespan of the installation (25 years). The system will be outdoors bearing extreme climatic conditions. To simulate the behavior of the system an international standard has been developed (IEC 26108), with which any high concentration photovoltaic product that is going to be found in the market must comply. This standard requires carrying out a series of tests that enable simulation of the expected system behavior onsite.

The high photovoltaic concentration modules must be mechanically connected to the structure of the tracker element in which it is going to be installed. This attachment must also contain the rotation axle or axles so that the module can position itself at all times perpendicularly to the direction of the solar rays in the degree that the tracker moves along the 2 axes (azimuth and inclination) throughout the day. Only in this way will the module be able to obtain maximum solar energy that will enable it to obtain the electric conversion efficiency for which it has been designed.

In current modules, these gripping and rotation axles are united to their own structure. In many cases this implies an important torsion stress on the module, giving rise, especially in methacrylate structures, to fissures and damage caused by seepage of water and/or mechanical misalignments that could sap the output or, even, negate module operation.

### SUMMARY OF THE INVENTION

The present invention refers to a high concentration photovoltaic module having essential features that represent an improvement and solution to the above-cited problems regarding the high photovoltaic concentration modules known to date.

The high concentration photovoltaic module of the invention comprises a plurality of solar energy concentrators consisting in Fresnel lenses, and a sealed type structure of drawing aluminum in a “V” shape, in which the interior and the base are attached in the central section by attachment means and on pre-established spaces in the structure, photovoltaic receivers each of which contain a photovoltaic cell, above which a secondary optic element, protection diode and connectors are attached.

The “V” shape of the support structure of the module of the invention allows to be less internal air, due to the reduced space given that the air inside, subjected to outside climatic conditions during a prolonged period of time, can condense itself leading to moisture in the interior. The module can also be compatible with the installation of a dehumidifying system that allows maintaining the relative humidity of the module's interior at very low levels, thus minimizing the effects that the moisture could have on the active system elements. Likewise, the support structure of the Fresnel lens arrays allows the Fresnel lenses to be placed frontward forming a string.

In short, the invention refers to a new system for applying solar radiation concentration lenses to photovoltaic cells in order to increase the electric energy production capacity of the same, whose operating system is established by the larger solar radiation intensity, received by the photovoltaic cell, when a concentration lens, having a greater surface than the cell, is placed between it and the solar rays, and a secondary element which in turn acts as a concentrator, flux homogenizer and chromatic mixer capable of increasing the radiation potential projected on the photovoltaic cell, thus improving the acceptance angle, increasing, consequently, the capacity of electric energy production of the same.

It must also be taken into consideration that the placement of the Fresnel lenses, solar radiation power concentrators of the array of photovoltaic cells of the receivers located in the module, also serve as a cover of the module where the cells are located, thus maintaining the accumulated heat concentration inside the module. That is, the concentrating lens fulfils a double function of strengthening the solar radiation and of protecting the cells in order to take better advantage of the temperature.

The system is based on the main operating principle of photovoltaic cells, which generate electric power when receiving solar irradiance. Consequently, by placing a solar radiation concentration lens, having a larger surface, in front of the photovoltaic cell, we increase the solar energy power on said photovoltaic cell, thus obtaining more radiation and, consequently, more electric energy production by the same. Said placement must be minutely calculated so as to ensure the perfect alignment of the center of the Fresnel lens and its respective receiver. To this end, the structure of the present invention has a pre-set relief to ensure that the photovoltaic receivers are installed in the optimal position during the manufacturing process.

As we mentioned previously, all of this implies very significant savings in the material employed in the construction of the photovoltaic modules, given that the number of photovoltaic cells used is considerably reduced, these being essentially the main element that increases production costs.

All of these considerations represent an important advance in the implantation of solar energy to be used in electric energy production systems, because it can be obtained at a much lower cost in comparison with the other systems for generating energy by means of conventional photovoltaic systems.

By means of a simple system the present invention offers the possibility of exploiting the concentration of solar rays within the Fresnel lenses taking advantage of the solar energy incoming an array of photovoltaic cells that transform this energy into electricity.

The module is composed of high efficiency photovoltaic cells produced with multijunction elements from groups III-V. The cells have a reduced size and on them solar light incomes said cells through special Fresnel type lenses, which allows functioning with very high concentration ratios (over 400 suns).

By making use of the elements described above it is possible to obtain efficiencies higher than twenty four percent (24%), which makes this technology an important candidate for entering into the high volume photovoltaic market, due to the fact that it enables generating electricity more economically than other technologies.

The module of the invention has a structure that enables insulating the cited components from the open air, thus avoiding water, dust or other elements from entering inside which could degrade the functioning of the same, thus guaranteeing a lifespan of more than 25 years.

The high concentration photovoltaic module of the invention is characterized in that it is an enclosing aluminum structure made by stamping with an airtight seal, having different production alternatives:
a) Semi-rigid polymeric material that enables sealing the structure without the need of employing chemical components. This system can be disassembled, making it possible to replace the primary lens or any other element inside the module.
b) Extruded aluminum profile sealing element, which enables putting pressure on the crystal and gaskets to likewise ensure sealing. This option also enables the disassembling of the lens and, therefore, having access to the interior of the module.
c) A seal using silicone supporting the array of lenses on a continuous perimeter bead that functions as a sealing gasket and closing the top with another continuous bead that closes at the corner above the lateral wing.

The array of primary lenses (a matrix of individual Fresnel lenses) is supported on an L shaped wing that covers the whole perimeter.

Afterwards the lens group and locking piece are inserted mechanically into the structure (cases a and b) or by using silicone (case c), thus sealing over the exterior wing of the aluminum structure.

The seal is made by covering the entire exterior perimeter of the structure.

Each module object of the invention is designed to provide around 35 watts of power in a 25° C. ambient temperature, although basically the system is scalable, and so it is possible to conceive modules with notably lower or higher power based on the same principles.

The present invention includes an adequate dissipation system for a high concentration (on the order of 400 to 500 suns, although scalable to concentration ratios of greater than 800 suns) on multijunction photovoltaic cells of less than a square centimeter. The new dissipation system is both economical and efficient, in with the reduction of costs that is obtained by the reduced surface area of the photovoltaic element is not negatively counterbalanced by the additional cost of the dissipation system.

The main object of the present invention is to provide a solar energy converter that optimizes the conversion of solar energy into electricity in a simplified structure that reduces manufacturing costs, thus reducing the cost per watt and eliminating the problems detected to date. Use of the object module of this patent is compatible in both solar plants and on rooftops, these understood to be both house and industrial roofs. It is important to emphasize that photovoltaic concentration had never been considered an option for electric energy generating on rooftops, the reason being that this type of module has been designed to be able to be used on flat trackers that occupy a minimum of space and do not have a notable visual impact. As it is a very light module, it can be integrated into flat trackers that can easily be installed on rooftops.

The present module is a simple and functional solution to the problems mentioned above, which permits an IP65, an index in compliance with international standard CEI 60529 that indicates the degree of protection of the anti access system of solid objects, dust, accidental contact or water. In this case, the two digits of the IP65 index indicate that the module of the invention does not allow any dust to penetrate, maintains the integrity of the internal electrical contacts, and does not allow water penetration, including a strong stream coming from any direction, and, in the case of seals a and b, it can be completely dismantled.

The present invention, in short, provides the possibility of multiplying the energy producing capacity of photovoltaic cells and their durability, obtaining in this way, with a considerable reduction in the amount of semiconductors used, a power in watts similar to and even greater than that produced by current modules, on account of their very superior levels of efficiency with respect of those obtained by conventional cells/panels, thus reducing the drawbacks arising from the need to obtain high performance without a significant cost increase, given that using a lower number of semiconductors results in a very important cost savings in the production of the photovoltaic modules.

Furthermore, the present invention includes an alternative to the attachment system of the module to the solar tracker that minimizes the torsion stress to which the module is subjected during normal tracker operation, by means of two metallic side parts screwed onto the structure. These pieces have housings in the outer sections that are perpendicular to the module base in order to brace the same to the axles/screws of a solar tracker.

### BRIEF DESCRIPTION OF THE DRAWINGS

To complete the description being made and for the purpose of aiding fuller comprehension of the features of the invention, a set of figures is included which forms an integral part of said description, having an illustrative and non-limiting function, wherein the following is represented:

FIG. 1 shows a lateral view of the high concentration photovoltaic module.

FIG. 2 shows a perspective view of the high concentration photovoltaic module.

FIG. 3 shows a section through III-III of FIG. 1.

FIG. 4 shows an exploded view of the high concentration photovoltaic module.

FIG. 5 shows a sectional perspective view of a portion of the photovoltaic module looking towards the interior.

FIG. 6 shows a sectional view through VI-VI of FIG. 1 of the high concentration photovoltaic module.

FIG. 7 shows a sectional view through VI-VI of FIG. 1 of the hermetically sealed high concentration photovoltaic module.

FIG. 8 shows a perspective view of the photovoltaic receiver.

FIG. 9 shows a sectional view of the module with an external attachment system to the tracker chassis.

FIG. 10 shows a lateral view of the module with an attachment system to the tracker chassis.

FIG. 11 shows a perspective view of the module with an attachment system to the tracker chassis.

In which the references represent:
1. L shaped perimeter wing
2. Fresnel lenses
3. Sealing gasket
4. Secondary optical element
5. Photovoltaic cell
6. V shaped structure
7. Wire connector
8. Decompression valve
9. Cable pass-through hole for positive lead
10. Cable pass-through hole for negative lead
11. Predetermined cavities
12. Connector terminal
13. Positive wire
14. Negative wire
15. Diode
16. Connection area
17. Receiver surface
18. Photovoltaic receiver
19. Locking piece or element
20. Tracker attachment piece

### PREFERRED EMBODIMENT OF THE INVENTION

To obtain a better understanding of the invention, the following is a description of the operating of the photovoltaic module.

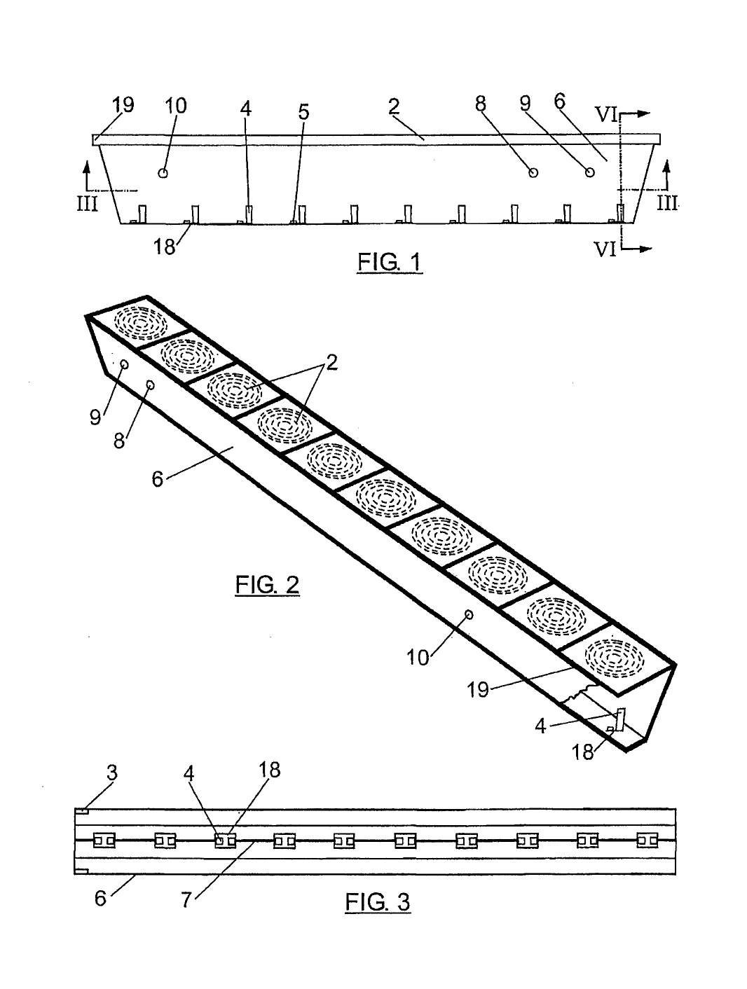

As shown in FIGS. 1-5, the photovoltaic concentration module consists on several solar energy concentrators for collecting solar radiation, each one of said concentrators comprising a Fresnel lens (2) as the primary optical element and a secondary optical element (4), which enables increasing the concentration level of the solar light located over photovoltaic receiver (18). The existence of a primary optical element and a secondary optical element improves the acceptance angle and provides uniform illumination of the cell, thus improving energetic efficiency of the photovoltaic cell. Secondary optical element (4) has an inverted truncated pyramid shape (with curved or straight lines) and is made of BK7 material (glass, borosilicate, with excellent optical qualities).

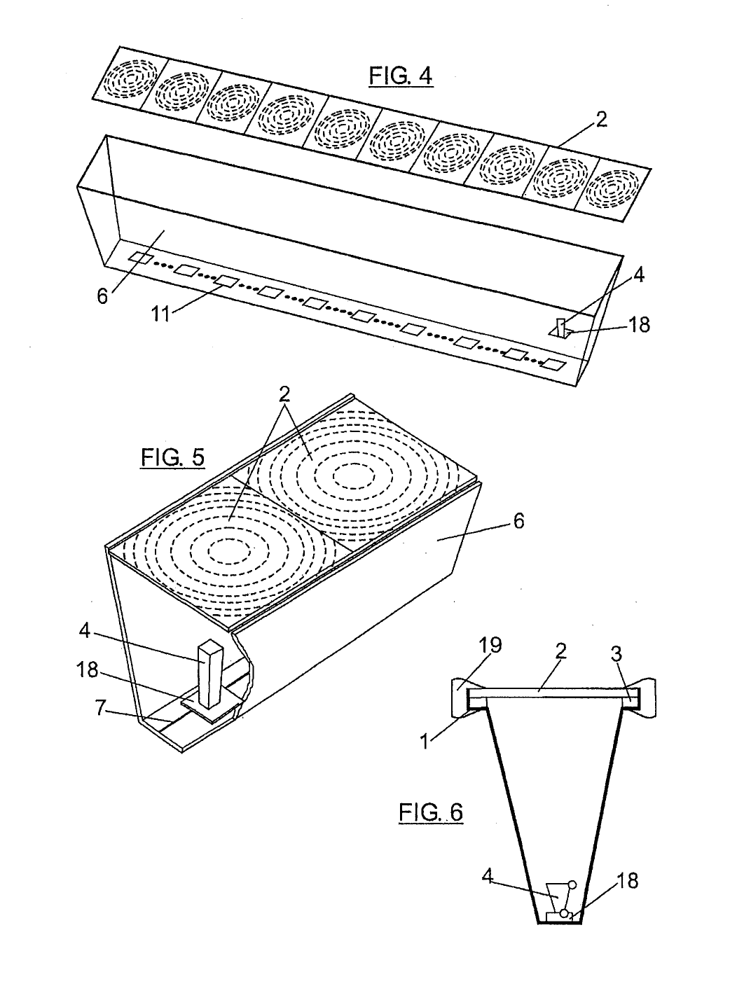

Said module is composed of a “V” shaped very lightweight drawing aluminum structure (6), as shown in FIGS. 2 and 4, manufactured as a drawn and hermetic structure with a flat central branch on the bottom part of the perpendicular structure, having predetermined cavities (11) to which photovoltaic receiver (18) is attached with a secondary optical element (4), as can be seen in FIG. 3. The “V” shape of the drawn aluminum structure prevents condensation inside the module. Indeed, the internal air, submitted to adverse climatic conditions during a prolonged period of time, can condense leading to moisture in the interior. The module is also compatible with the installation of a dehumidifying system in such a way allows to maintain the interior relative humidity of the module at very low levels, thus minimizing the effects that the moisture could cause on the system's active elements.

The “V” shaped structure (6) of the high concentration photovoltaic module of the present preferred embodiment, is manufactured with aluminum, in whose contoured cavities (11) of the mid-section of the base, photovoltaic receivers (18) are attached, comprising, as shown in FIG. 8, a photovoltaic cell (5), a protection diode (15) and two wire connectors, one positive (13), and the other negative (14) with their respective connector (1) on a connection conducting area (16) that is placed on the surface of receiver (17), which is made of ceramic material or metal alloys. Said photovoltaic receivers (18) are attached with an adhesive component that, furthermore, fulfils the function of transferring heat between said receiver and the aluminum surface, which, in turn, passively fulfils the heat dissipation function by transferring heat to the exterior. Said photovoltaic receivers (18) are installed in accordance with the number of Fresnel lenses present in the module, and are interconnected by means of a wire connector (7), as shown in FIG. 3.

The “V” shaped drawn aluminum structure serves as a support for the array of Fresnel lenses and as a heat projecting element for the photovoltaic cells. The Fresnel lenses are placed in line on the drawn aluminum structure.

FIG. 7 shows the front mount of the Fresnel lenses (2) that covers the photovoltaic module, made of glass, over which the Fresnel lenses are laminated. The array of lenses is attached to the aluminum structure by means of a hermetic seal system, made by placing a sealing gasket that covers the whole perimeter of the exterior wing over which the edge of the lens array is supported and a locking piece, made of aluminum or polymeric material that creates the exterior seal of the structure and lens. This seal can also be carried out by means of placing a bead of silicone on the base of the exterior wing, which in this case fulfils the sealing function of the gasket, and likewise sealing the array of lenses on the structure with silicone. In this way the interior of the module is isolated from the exterior.

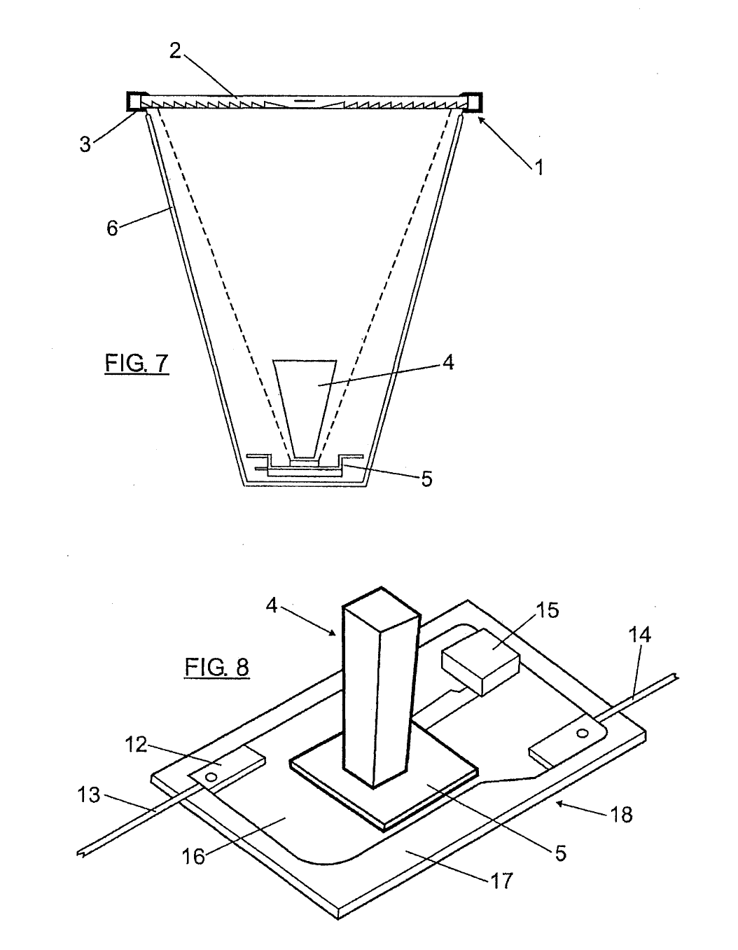

Furthermore, as can be seen in FIG. 6, the connection of Fresnel lenses (2) with the “V” shaped structure (6) can be done by means of locking elements (19) which, as a clamp, embrace perimeter L shaped wing (1) of structure (6) and the top perimeter of Fresnel lenses (2), ensuring the pressure of the lenses on the sealing gasket (3).

The connection of lenses (2) to the “V” shaped structure (6) can also be done with silicone or semi-rigid polymeric material in the manner of sealing gaskets and lock.

It must also be taken into consideration that the placement of Fresnel lenses (2), solar radiation power concentrators over the array of photovoltaic cells located in the module, also serves as a cover of the module where the receivers are located, thus maintaining the accumulated heat concentration inside the module. That is, the concentration lens fulfils the double function of increasing the solar radiation and of protecting the cells in order to take better advantage of the solar radiation.

Photovoltaic receivers (18) are positioned in cavities (11) pre-molded during production in the base of structure (6), as has been indicated above. In each cavity (11), in which a photovoltaic receiver (18) is going to be placed, metallic ceramic (or metal alloy) surface (17) is incorporated that constitutes the surface of photovoltaic receiver (18), and a secondary optical system (4) is also installed over photovoltaic cell (5) of these receivers (18) by means of a type of transparent rubber.

The present module can be connected to the tracker by means of two lateral attachment pieces (20) screwed into structure (6) at the base of the same, by means of two screws each. The housings for the axles/screws that connect to the tracker are found on the two lateral ends of these pieces.

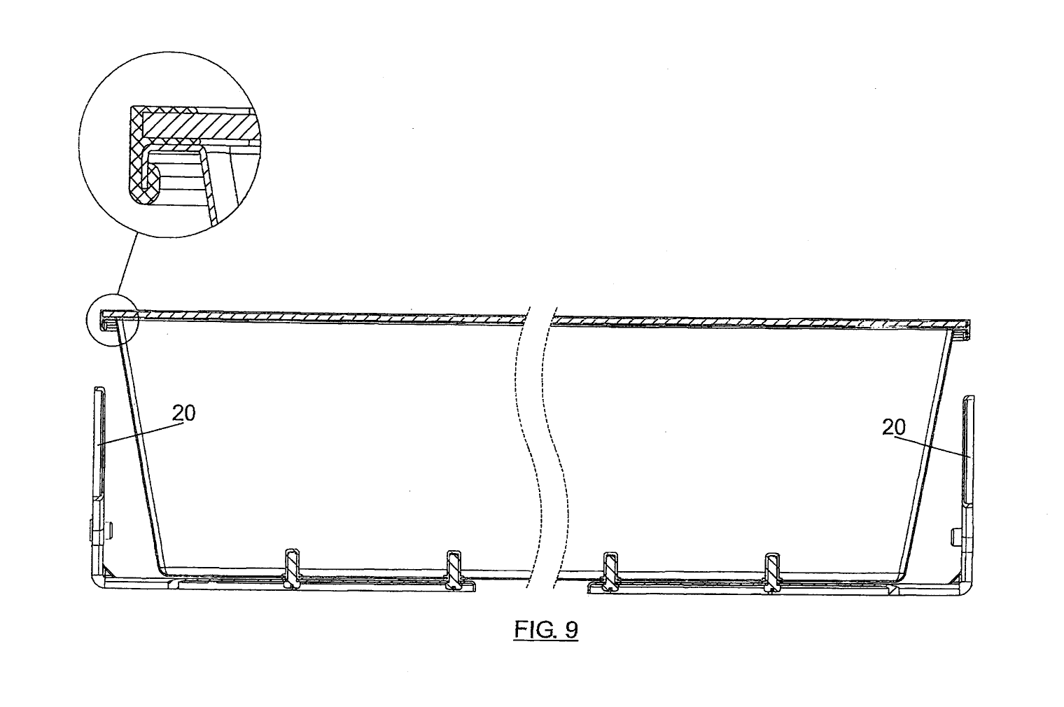

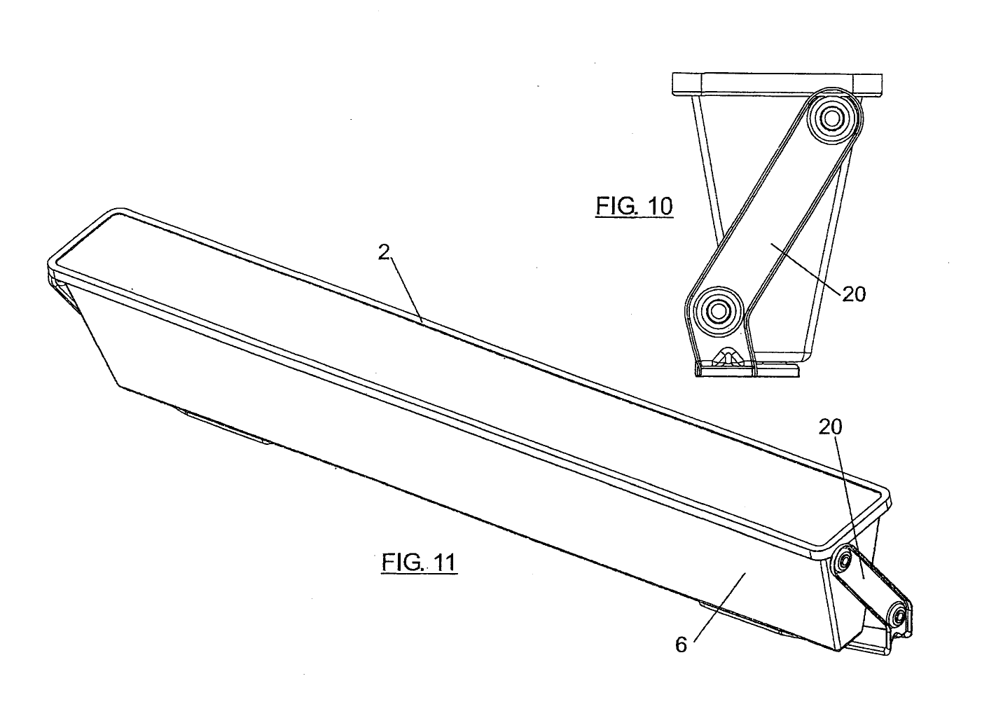

As can be seen in the different views displayed in FIGS. 9, 10 and 11, the two screwed in metallic pieces (20) are deployed, with two screws each, at the base of the structure by means of self threaded screw holes that have been made in the structure. By means of this system the rotation and torsion stress is not directly transmitted to the sides of the structure, thus decreasing potential deformations. Furthermore, this system simplifies setting up/dismounting the tracker, facilitating its installation, operation and maintenance.

As can be seen, the outer edges of the lateral pieces form an angle with respect of the base. In said zone of the pieces there are housings for the rotation axles/screws that are connected to the tracker.

The manufacturing process of truncated “V” shaped structure (6) is done by stamping (drawing) aluminum sheets with hydraulic presses that use a sequence of strokes to pre-shape the piece until it is finished. Piece or structure (6) has an L shaped perimeter wing (1) on which the array of Fresnel lenses (2) will be placed. On the base, the piece has housings or cavities (11) made in it for the photovoltaic receivers (18) in such a way that their subsequent placement will be done simply and precisely. The sides comprise two cable pass-through holes for the positive lead (9) and negative lead (10) for connection to the wires outside the module, as can be seen in FIG. 2, as well as a decompression valve (8).

The module assembly process comprises the following steps:
1. Manual or automatic inspection of the housing or cavity (11) marked on the aluminum base of the structure of the previously assembled receivers (18), which comprises the ceramic or metal alloy surface (17), the photovoltaic cell (5), the protection diode (15) and connectors (14, 13), by means of an adhesive component with thermal transfer properties. This operation is carried out as many times as number of Fresnel lenses (2) comprised in the array of lenses.
2. Series connection of all receivers (18) with wire connector (7) and making use of positive lead connector (14) and negative lead connector (13) (2 per receiver) of each receiver (18).
3. Connection to the exterior wires of the module, to the first and last connector of the row of receptors (18), exiting the module through the positive (9) and negative (10) cable pass-through holes made for this purpose.
4. Attaching decompression valve (8) to the housing provided for this purpose.
5. Placement of seal gasket (3) on the end of the external wing (a bead of silicone for type c seals).
6. Placement of the array of Fresnel lenses (2) on the L shaped perimeter wing.
7. Locking by means of locking piece (19).
8. Screwing in lateral attachment pieces to the tracker.
9. Finally, the module is characterized by means of a solar simulator to determine the power of the same, creating its I-V curve and classifying the module in accordance with these results.

1-14. (canceled)

15. A high concentration photovoltaic module comprising:
a plurality of concentration Fresnel lenses as solar radiation concentration lenses that constitute an array or group;
a “V” shaped structure on a top part of which the array of Fresnel lenses is located attached by a sealed attachment, and on an interior of which there is a plurality of pre-determined cavities, each one placed on a same parallel plane to each concentration Fresnel lens;
a plurality of interconnected photovoltaic receivers, each one placed in a predetermined cavity in an interior and base of the “V” shaped structure, and that comprise a receiver surface on which is placed at least one photovoltaic cell, one protection diode, and respective positive and negative connectors;
a plurality of secondary optical elements each one placed over the photovoltaic cell of each photovoltaic receiver; and
two lateral metallic pieces screwed to the base of the structure and including housings on their exterior zones, perpendicular to the base for the attachment of the same to axles/screws of a solar tracker.

16. A high concentration photovoltaic module in accordance with claim 15, wherein the lateral metallic pieces are screwed to the base of the structure through self-threaded screw holes that have been made in the structure.

17. A high concentration photovoltaic module in accordance with claim 15, wherein exterior ends of the lateral metallic pieces are inclined forming an angle with respect of the base.

18. A high concentration photovoltaic module in accordance with claim 15, wherein the “V” shaped structure includes an L shaped perimeter wing.

19. A high concentration photovoltaic module in accordance with claim 18, wherein the array of Fresnel lenses is attached to the “V” shaped structure by a locking piece along a full length of the exterior perimeter of the structure as a sealed and detachable means.

20. A high concentration photovoltaic module in accordance with claim 19, wherein the locking piece is made of extruded aluminum.

21. A high concentration photovoltaic module in accordance with claim 18, wherein the array or group of Fresnel lenses is attached to the “V” shaped structure by a sealing gasket as the sealed attachment.

22. A high concentration photovoltaic module in accordance with claim 15, wherein the array of Fresnel lenses is attached to the “V” shaped structure by a continuous perimeter silicone bead as the sealed attachment that serves a function of a sealed gasket and lock.

23. A high concentration photovoltaic module in accordance with claim 15, wherein the array of Fresnel lenses is attached to the “V” shaped structure by a semi-rigid polymeric material as the sealed attachment that serves a function of a sealing gasket and lock.

24. A high concentration photovoltaic module in accordance with claim 15, wherein the “V” shaped structure is made of extruded aluminum.

25. A high concentration photovoltaic module in accordance with claim 15, wherein the surface of the receiver of the photovoltaic receiver is made of a ceramic material or metal alloy.

26. A high concentration photovoltaic module in accordance with claim 15, wherein the “V” shaped structure comprises two cable pass-through holes for a positive lead and a negative lead for connection to the exterior cables of the module.

27. A high concentration photovoltaic module in accordance with claim 15, wherein the secondary optical elements are made of BK7 material.

28. A high concentration photovoltaic module in accordance with claim 15, wherein the secondary optical elements have a shape of a truncated inverted pyramid.
